(19) United States
(12) Patent Application Publication
(10) Pub. No.: US 2007/0279101 A1
(43) Pub. Date: Dec. 6, 2007

(54) Signal Output Circuit, Audio Signal Output Apparatus Using The Same, And Electronic Device

(76) Inventors: Takeshi Onodera, Kyoto (JP); Hideki Munenaga, Kyoto (JP); Satoshi Sakaidani, Kyoto (JP)

Correspondence Address: CANTOR COLBURN, LLP, 55 GRIFFIN ROAD SOUTH, BLOOMFIELD, CT, 06002, US

(21) Appl. No.: 11/578,813

(22) PCT Filed: Apr. 20, 2005
(86) PCT No.: PCT/JP05/07520

§ 371 Date: Oct. 19, 2006

(30) Foreign Application Priority Data
Apr. 21, 2004 (JP) 2004-125659

(51) Int. Cl. H03K 5/00

(52) U.S. Cl. 327/1

(57) ABSTRACT

A selection circuit switches the output between a ancillary PWM signal NS_{PWM} and a primary PWM signal S_{PWM} in accordance with a power supply transition period or normal period. A ancillary signal generating circuit generates a gradually rising signal which is then amplified by a second driver circuit, so that a DC block capacitor is gradually charged and discharged. Thereby, the occurrence of noise due to an inrush current is prevented.

### TECHNICAL FIELD

This invention relates to a signal output circuit, and it particularly relates to a signal output circuit having a function of preventing the occurrence of noise arising from an abrupt change in voltage waveforms at power-on or power-off.

### BACKGROUND TECHNOLOGY

In recent years of development done in the LSI technology, the 1-bit DAC (Digital Analog Converter) are used for the digital signal processing and the amplification thereof in the digital audio represented by CD players, MD players and the like. In this 1-bit DAC, the audio signals undergo the noise shaping by the use of a ΣΔ modulator and are then outputted as 1-bit signals which have been subjected to pulse-width modulation PWM (Pulse Width Modulation).

The 1-bit PWM signal is amplified to a predetermined level in order to drive a speaker which is a load. In so doing, a Class D amplifier by which high efficiency can be obtained is used. The amplified 1-bit PWM signal passes through a post lowpass filter so as to be an analog reproduced signal and is then reproduced as sound.

Here, in a case where the sound quality is given emphasis, a high-order ΣΔ modulator is generally employed for producing 1-bit PWM signals. Though this high-order ΣΔ modulator exceeds in pushing out the quantization noise beyond the human audible band, it is characterized by that the output cannot be made to gradually rise up at the start of operation. This abrupt rise of waveform caused by the high-order ΣΔ modulator is amplified by the Class D amplifier so as to cause an inrush current flowing into a DC-block capacitor. This inrush current irritates the auditory sense as undesirable noise from a speaker or headphone. By the same phenomenon the noise also occurs at the stop of operation.

In the light of this, as cited in Patent Document 1 as a conventional technique, a mute circuit is added between the DC-block capacitor provided in the load circuit and the speaker to prevent this noise. A control is performed such that this mute circuit is turned on at the timing of the occurrence of noise and the output is short-circuited to the ground potential so as to suppress the noise occurrence.

In the same reference, a method was disclosed in which this noise occurrence is suppressed in a manner that at the time of rise and fall a plurality of inverters are successively turned on and off in the Class D amplifier comprised of the plurality of inverters arranged in parallel.

[Patent Document 1]

Japanese Patent Application Laid-Open No. 2001-223537.

At the same time, mute element is required for the suppression of noise by the mute circuit and therefore the number of parts used is large. In addition, the mute control terminals and the connections around them are required, causing a problem in that the demand for reduced size of a set is not met.

### DISCLOSURE OF THE INVENTION

The present invention has been made in view of these problems and an object thereof is to provide a signal output circuit that restricts the noise due to an inrush current and reduces the circuit area.

An embodiment of the present invention relates to a signal output circuit. This signal output circuit comprises: a selection circuit which selects either a primary signal to be outputted basically or a ancillary signal to be outputted during a power transition period, in accordance with a normal period or a power transition period; a first driver circuit used in the normal period and a second driver circuit used in the power transition period which are provided for receiving an output of the selection circuit in parallel; and a signal generating circuit which generates the ancillary signal as a digital signal corresponding to a power transition, wherein outputs from the first driver circuit and the second driver circuit are coupled so as to be outputted.

According to this embodiment, a ancillary signal for use with soft start is amplified by the second driver circuit at power-on or power-off, at which time the noise occurs. Thereby the inrush current can be suppressed and the noise can be reduced.

In one embodiment of the present invention, the signal generating circuit may include: a filter circuit which smoothes a change in a digital signal indicative of a power transition; and a conversion circuit which converts an output of the filter circuit into a digital signal. The conversion circuit may be a first-order EA modulator.

The rising and falling of a ancillary signal are smoothed off by this filter circuit. Thus, when the ancillary signal is reproduced from a speaker, it can be made unlikely to be recognized as noise acoustically.

A design may be made such that a drive capability of the second driver circuit is lower that that of the first driver circuit.

The second driver circuit may include a resistance element provided in series in an output thereof, and in the signal output circuit an output of the resistance element and an output of the first driver circuit may be coupled so as to be outputted.

The load driving capability of the second driver circuit is set lower than that of the first driver circuit by adjusting the resistance element provided in series in the output of the second driver circuit or adjusting the transistor size, so that the noise level can be effectively suppressed. Furthermore, when the primary signal is reproduced by the first driver circuit, the effect of the second driver circuit can be made smaller.

In one embodiment of the present invention, it may further comprise a control circuit which at least controls a selection operation in the selection circuit and on-off of the first driver circuit. At power-on, this control circuit may firstly have the selection circuit select the ancillary signal and set the first driver circuit in an off state and, secondly, after the ancillary signal has been changed to a predetermined state, may turn the first driver circuit on and at same time have the selection circuit select the primary signal.

According to this embodiment, at power-on, the timing of signal selection by the selection circuit and the on-off switching of the first driver can be arbitrarily adjusted by the control circuit, so that the noise can be effectively suppressed.

At power-off, the control circuit may firstly turn the first driver circuit off in a state where the primary signal is being selected by the selection circuit and, thereafter, may have the selection circuit select the ancillary signal.

According to this embodiment, at power-off, the timing of signal selection by the selection circuit and the on-off switching of the first driver can be arbitrarily adjusted by the control circuit.

The signal output circuit may be integrated on a single semiconductor substrate.

Still another embodiment of the present invention relates to an audio signal output apparatus. This audio signal output apparatus comprises: an above-described signal output circuit; a filter which removes a high-frequency component of an output of the signal output circuit; and a speaker driven by an output signal of the filter.

According to this embodiment, the noise can be suppressed from being occurring from a speaker at power-on or power-off.

It is to be noted that any arbitrary combination of the aforementioned constituent elements and the expression of the present invention changed among a method, an apparatus, a system and so forth is also effective as the embodiments of the present invention.

### BRIEF DESCRIPTION OF THE DRAWINGS

FIG. 1 shows a digital audio signal output circuit using a signal output circuit according to an embodiment of the present invention.

FIG. 2 shows an operation waveform for each component of the signal output circuit of FIG. 1 and is a timing chart thereof.

### THE BEST MODE FOR CARRYING OUT THE INVENTION

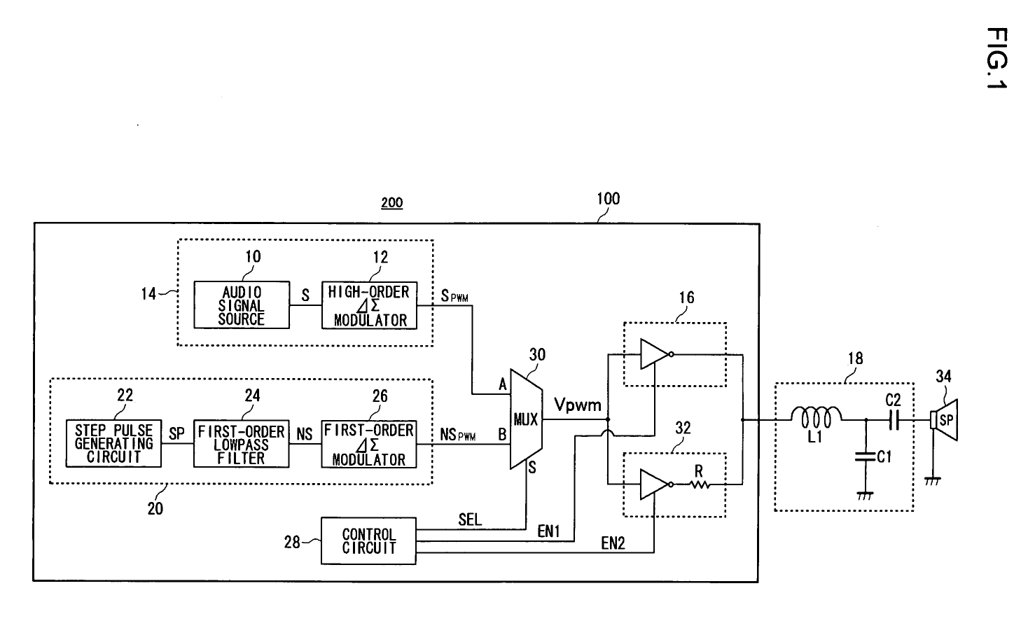

An embodiment of the present invention will be described with reference to FIG. 1. FIG. 1 is a circuit diagram showing a structure of an audio signal output apparatus 200 using a signal output circuit 100 according to an embodiment of the present invention.

An audio signal output apparatus 200 is installed in electronic equipment provided with audio output means such as a CD player or MD player, and includes a signal output circuit 100, a post lowpass filter 18 and a speaker 34. The signal output circuit 100 is a so-called digital amplifier, and outputs digital signals which have undergone pulse width modulation. The speaker 34 may be an earphone, a headphone or the like.

The post lowpass filter 18 includes a series inductor L1, a shunt capacitor C1 and a DC block capacitor C2. The post lowpass filter 18 removes the high-frequency components and DC components of digital signals outputted from the signal output circuit 100. This post lowpass filter 18 converts a digital signal, outputted from the signal output circuit 100, into an analog signal. The analog reproduced signal outputted from the post lowpass filter 18 is inputted to the speaker 34, from which an audio signal is outputted.

A signal output circuit 100 according to the present embodiment includes two signal generating circuits which produce a primary signal S and a ancillary signal NS, respectively, namely, a primary signal generating circuit 14 and a ancillary signal generating circuit 20, a selection circuit 30, a first driver circuit 16, a second driver circuit 32 and a control circuit 28.

Here, the primary signal S represents a signal having audio information or the like whereas the ancillary signal NS is a signal, for use with soft start, used to reduce noise at power-on or power-off.

As operating states in the present embodiment, there are a period during which normal audio is reproduced (hereinafter referred to as normal period) and a transition state which is at power-on or power-off (hereinafter referred to as power transition period), and the noise is reduced by controlling the operating state of a circuit in accordance with the two states.

Firstly, the principle of the signal output circuit 100 according to the present embodiment will be outlined. Generally, a high-order ΣΔ modulator 12 cannot gradually raise the voltage from the zero potential and hence the rising waveform at a power-on will be steep. In other words, in the output thereof it is difficult to produce a signal, as a PWM signal, whose duty ratio increases gradually from 0% onward. Thus, if an output signal of this high-order ΣΔ modulator 12 is directly amplified by the first driver circuit 16, an inrush current will flow into the DC block capacitor C2 used in a load circuit, which in turn produces noise.

In the light of this, a first-order ΣΔ modulator 26 which can cause the waveform to gradually rise up is provided separately from this high-order ΣΔ modulator 12. With this, a ancillary PWM signal NS_{PWM} is produced. And after raising it to a predetermined output voltage by this ancillary PWM signal NS_{PWM}, the modulator is switched to the high-order ΣΔ modulator 12 so as to suppress the noise. This first-order ΣΔ modulator 26 is not necessarily of the first-order and it may be a second-order ΣΔ modulator. It suffices if it can generate a PWM signal whose duty ratio increases sufficiently slowly not to cause noise. However, when the ΣΔ modulator is of the first-order as in the present embodiment, it is advantageous in that the circuit area can be made smaller.

As for the driver circuit, the second driver circuit 32 in which the drive capability has been lowered is provided in addition to the first driver circuit 16, for driving a speaker, used during a normal period, so that the noise is restricted by switching between the power transition period and the normal period. The main purpose of this second driver circuit 32 is not to drive the speaker 34 which is a load but is provided to gradually charge and discharge the DC block capacitor C2.

Hereinbelow, a description will be given in sequence of a flow of signals and a structure of each block. The signal generating circuit 14 which generates a primary signal (hereinafter referred to as a primary signal generating circuit) is comprised of an audio signal source 10 and a high-order ΣΔ modulator 12. A primary signal S outputted from the audio signal source 10 is converted to a primary PWM signal S_{PWM} by the high-order ΣΔ modulator 12. The high-order may be, for example, the fifth order. It may also be lower or higher than the fifth order. The design of the degree in the high-order ΣΔ modulator 12 may be set depending on the required sound quality or circuit scale.

On the other hand, the ancillary signal generating circuit 20 which generates a ancillary signal is comprised of a step pulse generating circuit 22, a first-order lowpass filter 24 and a first-order ΣΔ modulator 26. A stepwise pulse SP generated by the step pulse generating circuit 22 passes through the first-order lowpass filter 24 so as to become a gradually rising or falling ancillary signal NS. The first order ΣΔ modulator 26 performs a ΣΔ modulation on a ancillary signal NS and outputs it as a pulse-width modulated ancillary PWM signal NS_{PWM}. In other words, the first-order ΣΔ modulator 26 functions as a converter circuit which converts a ancillary signal NS, which is an output from the first-order lowpass filter 24, into a pulse-width modulated digital signal. The duty ratio of the ancillary PWM signal NS_{PWM} spreads and varies gradually starting from 0%.

These primary and ancillary two-system 1-bit PWM signals S_{PWM} and NS_{PWM} are inputted to the selection circuit 30. This selection circuit 30 has input terminals A and B and a control terminal S. A primary PWM signal S_{PWM} is inputted to the terminal A and a ancillary PWM signal NS_{PWM} is inputted to the terminal B. A control signal SEL from the control circuit 28 is inputted to the control terminal S, and it is assumed that the input of terminal A is outputted when the voltage thereof is high-level whereas the input of terminal B is outputted when it is low-level.

During a power transition period, the control circuit 28 outputs a low level as a control signal SEL. In this case, the selection circuit 30 selects a ancillary PWM signal NS_{PWM}, from the ancillary signal generating circuit 20, which is inputted to the input terminal B and outputs it. In a normal period during which the audio is reproduced, the control circuit 28 outputs a high level as a control signal SEL. Then the selection circuit 30 is so controlled as to select a primary PWM signal S_{PWM}, from the primary signal generating circuit 14, which is inputted to the terminal A.

Here, an important issue is the duty ratios of both the primary PWM signal S_{PWM} and the ancillary PWM signal NS_{PWM} at the instance when the output signal thereof is switched by the selection circuit 30 from the primary PWM signal S_{PWM} to the ancillary PWM signal NS_{PWM} or from the ancillary PWM signal NS_{PWM} to the primary PWM signal S_{PWM}. This is because when the duty ratios of the both PWM signals at the instance of the switching differ greatly from each other, the output voltage which has risen gradually by the ancillary signal NS_{PWM} becomes discontinuous at the instance of the switching and the noise due to an inrush current is caused there.

Thus, according to the present embodiment, two PWM signals, which are the primary PWM signal S_{PWM} and the ancillary PWM signal NS_{PWM}, are seamlessly connected together at the instance of the switching. At this instance of the switching, in order not to cause the inrush current to flow into the DC block capacitor C2 in the post lowpass filter 18 and furthermore in order not to cause undesirable noise, a design is made such that at this instance of the switching the duty ratio of the ancillary signal NS_{PWM} is equal to that of the primary signal S_{PWM} or is brought close thereto to a degree that it is not observed as noise.

For example, when the duty ratio of the primary PWM signal S_{PWM} at the time when the start-up of a high-order ΣΔ modulator 12 has been completed is 50%, it is preferable that a design be made such that the duty ratio of the primary PWM signal S_{PWM} at the time when the rising of primary PWM signal S_{PWM} has been completed is about 50% in order not to cause the switching noise at the time of a switching operation by the selection circuit 30.

The 1-bit PWM signal Vpwm which is selected by the selection circuit 30 and then outputted is inputted to a first driver circuit 16 and a second driver circuit 32 connected in parallel. This PWM signal Vpwm is amplified by the two driver circuits connected in parallel, and the outputs from the two driver circuits 16 and 32 are coupled again so as to be outputted to the post lowpass filter 18.

Here, the first driver circuit 16 is mainly provided for amplifying a primary PWM signal S_{PWM} during a normal period and is provided with an enable terminal. It is controlled by a control circuit 28 so that it is turned off during a power transition period.

The second driver circuit 32 is mainly used to amplify a ancillary PWM signal NS_{PWM} during a power transition period. Thus, the load drive capability thereof will be enough as long as the DC block capacitor C2 in the post lowpass filter 18 can be charged and discharged, and it is designed to be lower than the drive capability of the first driver circuit 16. According to the present embodiment, in the second driver circuit 16 there is provided a resistor R in the output thereof, and the load drive capability thereof is set lower.

Since the load drive capability of the second driver circuit 32 is lowered in this manner, the noise caused when switched from a ancillary signal to a primary signal is restricted. Furthermore, since the capability for the second driver circuit 32 to drive the speaker 34 is negligibly small compared to the capability for the first driver circuit 16 to drive the speaker 34, it is not indispensable that the second driver circuit 32 be turned off in a normal period during which a primary signal is outputed, thus increasing the design freedom.

The 1-bit PWM signal which has been amplified and combined by the driver circuits 16 and 32 are band-limited by the post lowpass filter 18. As a result, it is inputted, as an analog reproduced signal, to the speaker which 34 is a load and a user perceives the output of the speaker 34 as sound.

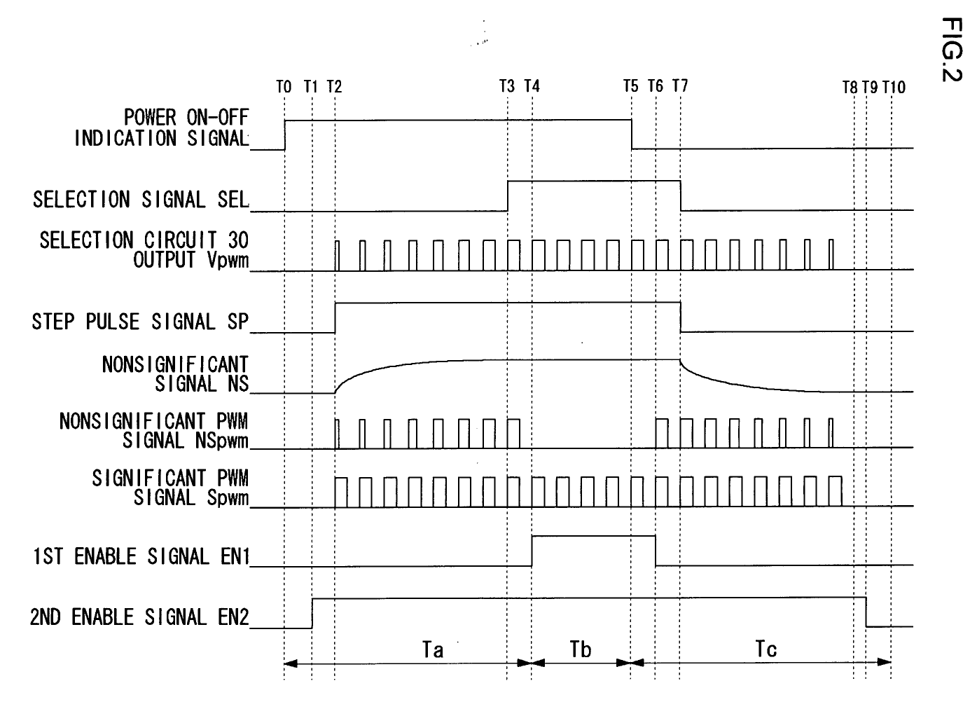

The above describes the structure of a circuit according to an embodiment of the present invention. Next, a description will be given, in a time sequentially manner, of an operation of the signal output circuit 100 structured as above, based on FIG. 2 that shows the operating state, output waveform and switching timing of each element.

In FIG. 2, time T0 denotes time when the power is applied. That the power is applied means that the power switch is turned on by the user, and then a power on-off indication signal, not shown in FIG. 1, is started.

Upon the start of the power on-off indication signal, the control circuit 28 sets an enable signal EN2 of the second driver circuit 32 (hereinafter referred to as second enable signal) to a high level at time T1 so as to turn on the second driver circuit 32. At this time, an enable signal EN1 of the first driver circuit 16 (hereinafter referred to as first enable signal) is set to a low level, so that the first driver circuit 16 is being tuned off.

Thereafter, a step waveform SP rises up at time T2 and a ancillary signal NS which has passed through the first-order lowpass filter 24 rises gradually. This ancillary signal NS is modulated into a 1-bit PWM signal by the first-order ΣΔ modulator 26 and is outputted as a ancillary PWM signal NS_{PWM} whose pulse width spreads gradually from 0%. At this time the selection signal SEL is being set to a low level, and the selection circuit 30 is so controlled as to output a ancillary PWM signal NS_{PWM}. During this time, the high-order ΣΔ modulator 12 in the primary signal generating circuit 14 is also started but is not selected by the selection circuit 30, so that a primary PWM signal S_{PWM} is not outputted.

When the duty ratio of the ancillary PWM signal NS_{PWM} has increased to a predetermined value and the output of the high-order ΣΔ modulator 12 thus becomes stable, the control circuit 28 switches the selection signal SEL to the high level at time T3. Thereby, the output of the selection circuit 30 is switched to a primary PWM signal S_{PWM}. If at the time T3 the duty ratios of the ancillary PWM signal NS_{PWM} and the primary PWM signal S_{PWM} are close to each other, the occurrence of noise can be restricted.

At this time, the first driver circuit 16 is turned off and the second driver circuit 32 is turned on. If the duty ratios do not coincide with each other, the charge-discharge capability of the DC block capacitor C2 will be restricted by the resistor R provided in the output of the second driver circuit 32. Hence, the noise sound at the time of the switching is unlikely to be audible from the speaker 34.

Thereafter, the control circuit 28 sets the first enable signal EN1 to the high level so as to turn the first driver circuit 16 on, which in turn completes a power transition period. In FIG. 2, the period denoted by Ta from time T0 until time T4 corresponds to a power transition period. Thereafter, it shifts to a normal period Tb. A primary signal S outputted from the audio signal source 10 is modulated into a primary PWM signal S_{PWM} by the high-order ΣΔ modulator 12, and amplified by the first driver circuit 16 and it passes through the post lowpass filter 18 so as to be supplied to the speaker 34 as a reproduced analog signal and then reproduced as sound.

In the power transition period Tc when the power is off, the above-described process at power-on is progressing in the reverse order. That is, the user stops the power supply at time T5, and at the same time the power on-off indication signal drops to a low level. Upon this, at time T6 the control circuit 28 sets the first enable signal EN1 to a low level and turns the first driver circuit 16 off. Thereafter, at time T7 the control circuit 28 sets the selection signal SEL to a low level, and the selection circuit 30 switches the output thereof from the primary PWM signal S_{PWM} to the ancillary PWM signal NS_{PWM}.

When at time T7 the step pulse signal SP becomes low level, the ancillary signal NS outputted from the first-order lowpass filter 24 is getting diminished in accordance with a time constant. As a result, the duty ratio of the ancillary PWM signal NS_{PWM} outputted from the first-order ΣΔ modulator 26 is expressed by a waveform where it becomes smaller gradually from about 50%. During this, the second driver circuit 32 only is turned on. And the noise does not disturb human ears and the output waveform is getting smaller. Thereafter, at time T8 the first-order ΣΔ modulator 26 and the high-order ΣΔ modulator are made to fall. At time T9, the second driver circuit 32 is turned off so as to complete a power-off process.

The present invention has been described based on the embodiments of the present invention. According to the present embodiments, the noise reproduced by a speaker at power-on or power off can be reduced. In addition, the need for external parts such as transistors for switching is eliminated, so that the signal output circuit 100 can be structured by the elements all available inside an LSI. Hence, the chip area and the substrate area can be reduced and a set can be made smaller in size.

It is understood by those skilled in the art that the embodiments are merely exemplary, various modifications to the combination of each component and process thereof are possible and such modifications are also within the scope of the present invention.

In the present embodiments, for example, a description has been given of a state where the second driver circuit 32 is constantly turned on during a normal period Tb. However, there are cases where it is effective to control the on-off by the second enable signal EN2, as appropriate, in accordance with the normal period Tb or the power transition periods Ta and Tc. If the second driver circuit 32 is turned off during the normal period Tb, it will be advantageous in that the power consumption can be suppressed.

In FIG. 1, a resistor R is provided in the output of second driver circuit 32 in order to lower the drive capability thereof. However, the same advantage can be obtained by adjusting the transistor size of a Class D amplifier used in the driver.

The electronic equipment having the audio signal output apparatus 200 according to the present embodiments includes a CD player or MD player described in the embodiments and, in addition, it can be widely used in an apparatus having output means of audio signals, such as a mobile-phone unit, PDA (Personal Digital Assistance), a digital still camera and a digital video camera.

What is claimed is:

1. A signal output circuit, comprising:
selection circuit which selects either a primary signal to be outputted basically or a ancillary signal to be outputted during a power transition period, in accordance with a normal period or a power transition period;
a first driver circuit used in the normal period and a second driver circuit used in the power transition period which are provided for receiving an output of said selection circuit in parallel; and
a signal generating circuit which generates the ancillary signal as a digital signal corresponding to a power transition,
wherein outputs from said first driver circuit and said second driver circuit are coupled so as to be outputted.

2. A signal output circuit according to claim 1, said signal generating circuit including:
a filter circuit which smoothes a change in a digital signal indicative of a power transition; and
a conversion circuit which converts an output of the filter circuit into a digital signal.

3. A signal output circuit according to claim 2, wherein the conversion circuit is a first-order ΣΔ modulator.

4. A signal output circuit according to claim 1, wherein a design is made such that a drive capability of said second driver circuit is lower that that of said first driver circuit.

5. A signal output circuit according to claim 4, wherein said second driver circuit includes a resistance element provided in series in an output thereof, and an output of the resistance element and an output of said first driver circuit are coupled so as to be outputted.

6. A signal output circuit according to claim 1, further comprising a control circuit which at least controls a selection operation in said selection circuit and on-off of said first driver circuit,
wherein, at power-on, said control circuit firstly has said selection circuit select the ancillary signal and sets said first driver circuit in an off state and, secondly, after the ancillary signal has been changed to a predetermined state, turns said first driver circuit on and at same time has said selection circuit select the primary signal.

7. A signal output circuit according to claim 1, further comprising a control circuit which at least controls a selection operation in said selection circuit and on-off of said first driver circuit,
wherein, at power-off, said control circuit firstly turns said first driver circuit off in a state where the primary signal is being selected by said selection circuit and, thereafter, has said selection circuit select the ancillary signal.

8. A signal output circuit according to claim 1, wherein said circuit is integrated on a single semiconductor substrate.

9. An audio signal output apparatus, comprising:
a signal output circuit according to claim 1;
a filter which removes a high-frequency component of an output signal of said signal output circuit; and
a speaker driven by an output signal of said filter.

10. An electronic apparatus including an audio signal output apparatus according to claim 9.
